(19) United States
(12) Patent Application Publication
(10) Pub. No.: US 2009/0186464 A1
(43) Pub. Date: Jul. 23, 2009

(54) Method for producing bonded wafer

(75) Inventors: Nobuyuki Morimoto, Tokyo (JP); Hideki Nishihata, Tokyo (JP); Hidehiko Okuda, Tokyo (JP); Akihiko Endo, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SUMCO CORPORATION, Tokyo (JP)

(21) Appl. No.: 12/321,725

(22) Filed: Jan. 22, 2009

(30) Foreign Application Priority Data
Jan. 23, 2008 (JP) 2008-012,459

(51) Int. Cl. H01L 21/30

(52) U.S. Cl. 438/459; 257/E21.598

(57) ABSTRACT

In the method for producing a bonded wafer by bonding a wafer for active layer to a wafer for support layer and then thinning the wafer for active layer, when oxygen ions are implanted into the wafer for active layer, the implantation step is divided into two stages conducted under specified conditions.

### BACKGROUND OF THE INVENTION

1. Field of the Invention

This invention is to effectively prevent deterioration of surface roughness and occurrence of defects particularly resulted from an oxygen ion implanted layer in the production of a bonded wafer.

2. Description of the Related Art

As a typical production method of a bonded wafer, there are known a method wherein a silicon wafer having an oxide film (insulating film) is bonded to another silicon wafer and then one side of the resulting bonded wafer is ground and polished to form SOI layer (grinding-polishing method), a method wherein oxygen ions are implanted into an interior of a silicon wafer and thereafter a high-temperature annealing is conducted to form a buried oxide film in the silicon wafer and then an upper portion of the oxide film is rendered into SOI layer (SIMOX), and a method wherein ions of hydrogen or the like are implanted into a surface layer portion of a silicon wafer for SOI layer (wafer for active layer) to form an ion implanted layer and thereafter the wafer is bonded to a silicon wafer for support substrate and then the bonded wafer is exfoliated at the ion implanted layer through a heat treatment to form SOI layer (smart cut method).

Among the above methods, however, the grinding-polishing method has a problem that the thickness uniformity of the active layer is poor (±30% or more). On the other hand, the method using oxygen ion implantation (SIMOX) has a problem that SOI structures having different crystal orientations can not be produced so as to interleave the insulating layer.

As a solution for the above problems, the inventors have already developed a process of combining the oxygen ion implanting method with the grinding-polishing method, namely “a method for producing a bonded wafer by directly bonding a wafer for active layer having or not having an insulating film on its surface to a wafer for support layer and then thinning the wafer for active layer, which comprises time-orientedly combining a step of implanting oxygen ions into the wafer for active layer to form an oxygen ion implanted layer in the active layer, a step of subjecting the wafer for active layer to a heat treatment at a temperature of not lower than 1100° C. in a non-oxidizing atmosphere, a step of bonding the wafer for active layer to a wafer for support layer, a step of conducting a heat treatment for increasing a bonded strength, a step of grinding a portion of the wafer for active layer in the resulting bonded wafer short of the oxygen ion implanted layer, a step of further polishing or etching the wafer for active layer to expose the oxygen ion implanted layer, a step of oxidizing the bonded wafer to form an oxide film on the exposed surface of the oxygen ion implanted layer, a step of removing the oxide film, and a step of heat-treating at a temperature of not higher than 1100° C. in a non-oxidizing atmosphere”, and have disclosed in Japanese Patent Application No. 2006-184237 (corresponding to JP-A-2008-016534 published on Jan. 24, 2008).

By the method disclosed in the above patent application, it is made possible to directly provide a bonded wafer being excellent in the thickness uniformity of the active layer and relatively less in the defects as evaluated by a transmission electron microscope (TEM).

### SUMMARY OF THE INVENTION

The invention is concerned with an improvement in the production technique of the bonded wafer disclosed in the above patent application and is to propose a method for producing a bonded wafer which further reduces the occurrence of defects.

The inventors have made various studies in order to attain further reduction of wafer defects in the production method of the bonded wafer described in the above patent application, and found that the desired object is advantageously achieved by dividing the oxygen ion implantation from the conventional single stage into two stages and optimizing ion implantation conditions at each of the above two stages, particularly a substrate temperature in the implantation. The invention is based on the above knowledge.

That is, the summary and construction of the invention are as follows.

1. A method for producing a bonded wafer by bonding a wafer for active layer to a wafer for support layer with or without an insulating film and then thinning the wafer for active layer, which comprises time-orientedly combining:

(1) a step of forming an oxygen ion implanted layer in the wafer for active layer through at least two stages comprising a first implantation stage of implanting oxygen ions at a dose of 2×10¹⁶−5×10¹⁷ atoms/cm² into the wafer for active layer being at a state of not lower than 200° C. and a second implantation stage of implanting oxygen ions at a dose of 1×10¹⁵−2×10¹⁶ atoms/cm² into the wafer for active layer being at a state of lower than 200° C.;

(2) a step of subjecting the wafer for active layer to a first heat treatment at a temperature of not lower than 1000° C. in a non-oxidizing atmosphere;

(3) a step of bonding the wafer for active layer to the wafer for support layer directly or with an insulating film;

(4) a step of subjecting the bonded wafer to a second heat treatment to improve the bonded strength;

(5) a step of thinning a portion of the wafer for active layer in the bonded wafer to expose the oxygen ion implanted layer;

(6) a step of removing the oxygen ion implanted layer from the wafer for active layer in the bonded wafer; and

(7) a step of planarizing and/or thinning the surface of the wafer for active layer in the bonded wafer.

2. A method for producing a bonded wafer according to claim 1, wherein a crystal orientation of each wafer face in the bonded wafer is a combination of (100) and (110) or (111).

According to the invention, there can be stably obtained the bonded wafer having not only the excellent thickness uniformity after the thinning but also good surface roughness and being much fewer in the occurrence of defects.

### BRIEF DESCRIPTION OF THE DRAWING

The patent or application file contains at least one drawing executed in color. Copies of this patent or patent application publication with color drawings will be provided by the Office upon request and payment of the necessary fee.

The invention will be described with reference to the accompanying drawings, wherein:

FIG. 1 is a flow chart of production steps according to the method of the invention;

FIG. 2(a) is an optical microphotograph showing an ellipsoidally-shaped crystal defect generated on a wafer surface obtained in Example 1;

FIG. 2(b) is an optical microphotograph showing a linearly-shaped crystal defect generated on a wafer surface obtained in Example 2;

FIG. 3 is a photograph of a cross-section in a linearly-shaped crystal defect observed by TEM; and

FIG. 4 is a graph showing an influence of a dose in each of the first and second oxygen ion implantations on a defect density of a wafer.

### DESCRIPTION OF THE PREFERRED EMBODIMENTS

The invention will be concretely described below.

At first, the background of elucidating the invention will be described. As previously mentioned, the conventional oxygen ion implantation has been conducted at a single stage under conditions of an acceleration voltage: 150 keV and a dose: about 5.0×10¹⁶ atoms/cm². The inventors have inspected the defect density in the silicon wafer for active layer after oxygen ions are implanted under the above conditions and found that one or more defects per cm² are existent as macroscopically evaluated by a defect evaluation method (optical microscope observation or evaluation of HF defects).

As a cause on the above fact, it is considered that the damage in the ion implanting step is large and begins to generate defects when oxygen ions implanted are converted into oxygen precipitates (SiO₂) through a heat treatment in a reducing atmosphere before bonding or a heat treatment for increasing the bonded strength after bonding, which penetrate through the side of the active layer, resulting in the increase of the defect density in a final product.

Now, the inventors have discussed solutions for the above problem and obtained the following knowledge.

The oxygen ion implantation is divided into two stages. In the first stage, oxygen ion implantation is conducted so as to form a SiO₂ layer acting as a polishing stop layer or an etching stop layer. Since this ion implantation requires a large dose (2×10¹⁶−5×10¹⁷ atoms/cm²), however, it is required to raise the substrate temperature to not lower than 200° C. in order to minimize defective damage in the implantation as far as possible.

Subsequently, the second stage of the oxygen ion implantation is conducted at a relatively small dose (1×10¹⁵−2×10¹⁶ atoms/cm²) at a state that the substrate temperature is lower than 200° C. Although the dose in the second stage is small, since oxygen ions are implanted at a lower temperature, an amorphous layer is formed in the vicinity of a surface layer of the substrate.

Therefore, the growth of crystal defect generated when oxygen ions implanted at the first stage are converted into oxygen precipitates (SiO2) through a heat treatment at a post-step is suppressed by the amorphous layer formed in the second ion implantation stage.

By the aforementioned mechanism can be reduced crystal defects on the surface layer of the bonded wafer.

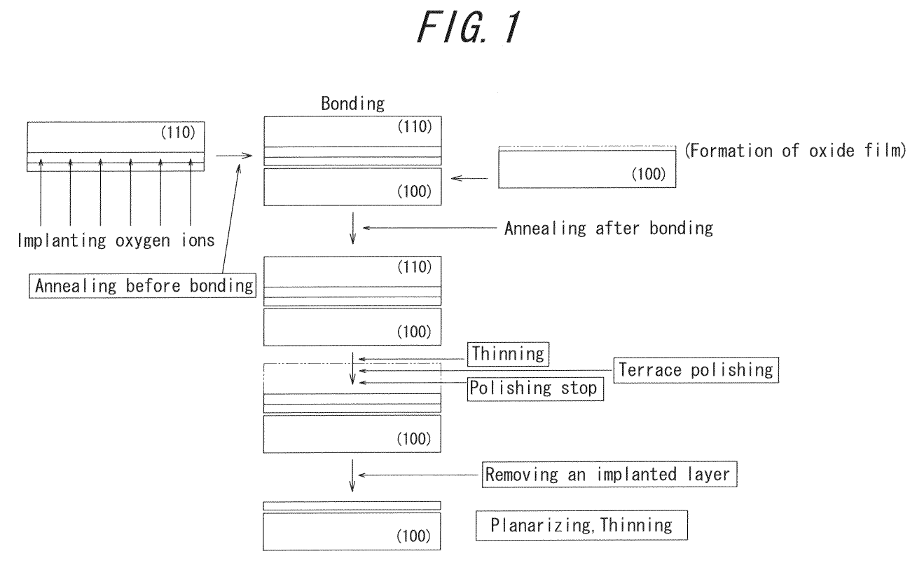

At first, the invention will be concretely described with respect to a bonded wafer substrate and each production step according to a flow chart shown in FIG. 1.

In the production of the bonded wafer, two silicon wafers, i.e. a wafer for active layer and a wafer for support layer are bonded to each other. The invention is applicable to not only a case that the bonding of both wafers is conducted with an insulating film (oxide film) but also a case that both the wafers are directly bonded without such an insulating film.

Moreover, a kind and a concentration of a dopant, a concentration of oxygen and the like are not limited as long as the wafer to be bonded has a good surface roughness suitable for bonding. In order to more reduce defects, however, it is preferable to use a wafer having no COP or a less COP. For the reduction of COP may be applied a method of reducing COP by optimizing CZ drawing conditions, a method of subjecting a wafer to a high-temperature heat treatment of not lower than 1000° C. in a reducing atmosphere after mirror working, a method of epitaxial-growing Si on a wafer by CVD or the like, and so on.

In such a production method of the bonded wafer, the invention effectively prevents the deterioration of surface roughness and the occurrence of defects, which are feared when the thickness of the insulating film is as thin as not more than 50 nm, particularly when the insulating film is not existent.

(1) Step of Implanting Oxygen Ions into a Wafer for Active Layer

In the invention, the acceleration voltage in the oxygen ion implantation may be properly selected depending on the thickness of the active layer in the final product and is not particularly limited. Therefore, the oxygen ion implantation may be carried out at an acceleration voltage of about 100-300 keV for a usual oxygen ion implanter.

In the first oxygen ion implantation stage, the dose is required to be within a range of 2×10¹⁶ to 5×10¹⁷ atoms/cm². When the dose in the first oxygen ion implantation stage is less than 2×10¹⁶ atoms/cm², the formation of SiO₂ layer is not sufficient and the polishing stop cannot be conducted properly, while when it exceeds 5×10¹⁷ atoms/cm², even if the implantation is conducted at a higher substrate temperature, the implantation damage becomes large and the number of defects increases. A preferable dose for conducting the polishing stop is 2×10¹⁶ to 2×10¹⁷ atoms/cm². On the other hand, when the etching stop is conducted with an alkali solution, SiO₂ layer as a stop layer is required to be completely continuous, so that the dose is preferable to be about 1×10¹⁷ to 5×10¹⁷ atoms/cm².

It is important for the invention that the substrate temperature in the first oxygen ion implantation is not lower than 200° C. More preferably, the substrate temperature is not lower than 400° C. but not higher than 600° C. Moreover, if the temperature exceeds 600° C., it is difficult to heat the substrate in the ion implantation.

The dose in the second oxygen ion implantation is required to be within a range of 1×10¹⁵ to 2×10¹⁶ atoms/cm². When the dose in the second oxygen ion implantation is less than 1×10¹⁵ atoms/cm², an amorphous layer is not formed sufficiently and the effect of stopping the growth of crystal defect is small, while when it exceeds 2×10¹⁶ atoms/cm², the whole of the surface layer becomes amorphous and the active layer does not form a single crystal.

In the second oxygen ion implantation, the substrate temperature is required to be lower than 200° C. When it exceeds 200° C., the amorphous layer is not formed sufficiently and the effect of stopping the growth of crystal defect is small. Preferably, the substrate temperature is not lower than room temperature (about 20° C.) but not higher than 100° C. Moreover, in order to make the temperature to not higher than room temperature, it is required to add a mechanism for forcedly cooling the wafer to the implanter.

Furthermore, it is advantageous to conduct the cleaning between the first and second ion implantation stages. Because, particles generated in the first ion implantation stage act as masks in the second ion implantation stage, and hence ions may not be implanted to portions corresponding to the particles. As a result, the amorphous formation is not sufficiently conducted in these portions, and there is a risk that the shooting of defects results in a cause of generating the defects. Similarly, the first ion implantation stage may be divided into plural times, and the cleaning may be carried out therebetween. Moreover, as the cleaning means, it is preferable to use SCl, HF, O₃ and an organic acid having an excellent performance for removing the particles. Also, the scrub cleaning for physically removing the particles may be applied.

(2) Step of Subjecting Wafer for Active Layer to First Heat Treatment

The wafer for active layer having the oxygen ion implanted layer formed in its active layer as mentioned above is subjected to a heat treatment at a temperature of not lower than 1000° C. in a non-oxidizing atmosphere of hydrogen, argon or the like. As a result, the form of the oxygen ion implanted layer becomes at a relatively continuous state, and the surface roughness is highly improved and the occurrence of defects can be suppressed at the subsequent time of exposing the oxygen ion implanted layer.

The heat-treating temperature is required to be not lower than 1000° C. as mentioned above. When the heat-treating temperature is lower than 1000° C., the oxygen ion implanted layer having a sufficient continuity is not formed and only the result similar to the case not conducting the heat treatment is obtained. On the other hand, if the heat-treating temperature exceeds 1250° C., there is a fear of generating slip displacement. Therefore, the heat-treating temperature is preferable to be within a range of 1000-1250° C.

In particular, a preferable condition for the polishing stop is that the wafer is kept at a temperature of 1000-1200° C. for not less than 1 hour. On the other hand, when the etching stop is conducted with an alkali solution, SiO₂ layer as a stop layer is required to be completely continuous, it is preferable that the wafer is kept at a temperature of 1200-1350° C. for not less than 5 hours.

Moreover, the heat treatment is not particularly limited because it is applicable to not only a batch type furnace but also various heating systems such as sheet-feed type lamp heating, resistance heating, flash annealing and the like. Preferably, the heat treatment is conducted for not less than 1 hour in case of using the batch type furnace and for not less than 10 seconds in case of using the sheet-feed type furnace. In short, it is enough to optimize the heat-treating time of each of the apparatuses considering the productivity.

(3) Step of Bonding Wafer for Active Layer to Wafer for Support Layer

Then, the wafer for active layer is bonded to the wafer for support layer. In this case, both the wafers may be bonded to each other with or without an insulating film.

When the bonding is conducted with the insulating film, it is preferable to use an oxide film (SiO₂), a nitride film (Si₃N₄) or the like as the insulating film. As a film formation method are preferable a heat treatment in an oxidizing atmosphere or a nitrogen atmosphere (thermal oxidation, thermal nitriding), CVD and so on. As the thermal oxidation, wet oxidation using steam can be used in addition to the use of oxygen gas. Moreover, the insulating film may be formed on the front-side substrate before or after the oxygen ion implantation. Also, the formation of the insulating film can be carried out on either the wafer for active layer or the wafer for support layer or both.

Further, the cleaning treatment is required before the bonding to suppress the occurrence of voids due to the particles. As the cleaning means, it is effective to use a general method for cleaning silicon wafer with SC1+SC2, HF+O₃, an organic acid or a combination thereof.

In addition, it is advantageous that the surface of silicon before the bonding is subjected to an activation treatment with plasma using oxygen, nitrogen, He, H₂, Ar or a mixed atmosphere thereof for enhancing the bonded strength.

In case of the direct bonding, H₂O adsorbed on the surface to be bonded changes into Sio₂ through the subsequent heat treatment, which is existent in the bonded interface, so that the formation of SiO₂ may be suppressed by cleaning the faces to be bonded with HF and then bonding their hydrophobic faces with each other. Thus, the oxide can be reduced at the bonded interface to bring about the improvement of device properties.

(4) Step of Second Heat Treatment for Improving Bonded Strength

The heat treatment for improving the bonded strength is preferable to be conducted at a temperature of not lower than 1100° C. for not less than 1 hour in order to sufficiently improve the bonded strength. The atmosphere is not particularly limited, but an oxidizing atmosphere is used for protecting the rear face of the wafer at grinding, polishing and etching steps used in the subsequent step of thinning the thickness of the portion in the wafer for active layer or the subsequent step of exposing the oxygen ion implanted layer. Thus, an oxide film having a thickness of not less than 150 nm is preferably formed.

(5) Step of Thinning Wafer for Active Layer to Expose Oxygen Ion Implanted Layer

As a method of exposing the oxygen ion implanted layer can be used the grinding, polishing, etching or a combination thereof. They may be selected properly considering costs for the thinning (costs for processing speed and processing device). In general, the grinding is advantageous in terms of cost.

The grinding of the wafer for active layer in the bonded wafer is carried out by a mechanical work. In this grinding, a part of the wafer for active layer is left on the surface side of the oxygen ion implanted layer. The thickness of the part of the wafer for active layer to be left is not particularly limited.

The wafer for active layer is preferably ground just before the oxygen ion implanted layer in order to shorten the time of the subsequent alkali etching or polishing step. However, considering the precision of the grinding device and the damage depth through the grinding (about 2 μm), the thickness of residual Si film is preferable to be about 3-10 μm.

Moreover, the etching with an alkali solution may be conducted instead of the grinding. In this case, in order to avoid the etching of the rear face of the wafer for support layer, it is desirable to form a protection film such as an oxide film or the like on the rear face of the wafer.

Continuously, the oxygen ion implanted layer is exposed by grinding or etching as described below.

Grinding Process (Grinding stop)

When the grinding process is utilized as a treatment for thinning the layer, it is preferable to conduct the grinding while feeding a grinding solution having an abrasive concentration of not more than 1 mass %. As the grinding solution is mentioned an alkaline solution having an abrasive (e.g. silica) concentration of not more than 1 mass %. Moreover, as the alkaline solution is preferable an inorganic alkali solution (KOH, NaOH or the like), an organic alkali solution (for example, piperazine composed mainly of amine, ethylene diamine or the like), or a mixed solution thereof.

In this grinding process, since the abrasive concentration is not more than 1 mass %, the mechanical grinding action with the abrasives is hardly caused, and the chemical grinding action is preferential. Thus, a part (Si layer) of the wafer for active layer is ground by the chemical grinding action with the alkaline solution. Since the etching rate ratio of Si/SiO, in the alkaline solution is high, the Si layer as a part of the wafer for active layer can be ground efficiently, whereas the SiO₂ layer is hardly ground. Even if the mechanical accuracy of the grinding device is insufficient, only the Si layer is ground without substantially grinding the oxygen ion implanted layer, so that the oxygen ion implanted layer can be exposed uniformly.

Moreover, as compared with the following etching process, the merit of the grinding process lies in a point that a thin film having an excellent in-plane thickness uniformity can be formed without giving any damage to the Si active layer as a part of the front side silicon wafer isolated by the oxygen ion implanted layer, even if the oxygen ion implanted layer is not a completely continuous SiO₂ layer.

Etching Process (Etching Stop)

In the above film thinning treatment, the front side silicon wafer located at the grinding side of the oxygen ion implanted layer can also be removed by using an alkaline etching solution. As the alkaline etching solution is used, for example, KOH, NaOH or the like. Also, an aqueous solution of tetramethyl ammonium hydroxide (TMAH) having a high etching rate ratio (selectivity) between silicon and SiO₂ can be used. The use of TMAH is more preferable because it contains no metal ion such as K or Na and is less in the influence on the device.

When the SiO₂ layer formed in the oxygen ion implanted layer is not continuous, the alkali solution may insert from spaces between SiO₂ particles to etch out a part of the active layer. In order to prevent this phenomenon, it is preferable that the heat treatment before the bonding and/or the heat treatment for enhancing the bonded strength is conducted at a high temperature of not lower than 1200° C. for not less than 5 hours.

Combination of Etching Process and Grinding Process

The oxygen ion implanted layer may be exposed by a combination of the etching process and the grinding process.

In particular, when Si is etched before the grinding, a boundary between the terrace (an outer peripheral region of 1-3 mm not bonding two wafers to each other) and the bonded region becomes smooth to suppress the occurrence of particles. Moreover, only the terrace may be ground before the grinding process.

(6) Step of Removing Oxygen Ion Implanted Layer

The exposed oxygen ion implanted layer must be removed because many crystal defects due to the formation of SiO₂ or the ion implantation are existent therein. As the removing method, there are an etching process, an oxidation process, a grinding process and the like.

Etching Process

This etching process is a method of removing SiO₂ by immersing in HF solution, wherein the wafer is immersed in a 3-50% HF solution for about 1-30 minutes. In case of the bonded wafer with the oxide film, since the oxide film is exposed at the peripheral portion (terrace) of the wafer, the oxide film is etched out by immersing in the HF solution of a high concentration for a long time. If the etched amount is large, the active layer is exfoliated at the peripheral portion of the wafer, resulting in the occurrence of the particles. Therefore, a goal for the removal of SiO₂ is preferable to be a condition that the surface of the wafer as a whole becomes a water-repellent surface.

Also, the oxygen ion implanted layer is a mixed layer of SiO₂ and Si depending on the oxygen dose and heat-treating conditions, which may not be removed by HF immersion completely.

In any cases, when the heat treatment before the bonding or the heat treatment for enhancing the bonded strength is a low-temperature, short-time treatment not forming the complete SiO₂ layer, the crystal defects existing in the vicinity of the oxygen ion implanted layer cannot be completely removed, so that the removal step of the defect region is further required.

Oxidation Process

This process comprises a step of forming an oxide film of a given thickness on the exposed surface of the oxygen ion implanted layer and a step of removing the resulting oxide film.

Since it is enough to conduct the oxidation in an oxidizing atmosphere, the treating temperature is not particularly limited, but is preferably 600-1100° C. in the oxidizing atmosphere.

However, when many crystal defects are existent in the oxygen ion implanted layer, a treatment at a lower temperature, preferably about 600-900° C. is preferable in order to suppress the growth of the crystal defects into the active layer during the heat treatment. When the oxidation is conducted at the lower temperature, a wet oxidation using H₂O vapor or a hydrochloric acid oxidation including an oxidizing gas such as HCl gas may be applied for increasing a growing rate of the oxide film, which is more preferable for obtaining a high throughput.

The thickness of the oxide film is not particularly limited, but if the crystal defect layer is existent in the oxygen ion implanted layer, it is preferable to be larger than the thickness of the crystal defect layer. The thickness is preferable to be about 100-500 nm under the conditions of oxygen ion implantation according to the invention. When the thickness of the oxide film is less than 100 nm, the crystal defect region can not be removed sufficiently, while when it exceeds 500 nm, the thickness uniformity of the active layer is deteriorated due to the breakage of the in-plane uniformity of the oxide film.

The removal of the oxide film may be conducted by cleaning with HF solution or by etching through annealing with hydrogen gas or Ar gas or a gas containing HF. Here, the above oxidation treatment and removal treatment may be conducted plural times. Thus, it is possible to conduct more thinning of the active layer while maintaining the planarized surface roughness.

After the removal of the oxide film, it is advantageous to remove the particles and metallic impurity attached to the surface of the bonded wafer by immersing the bonded wafer in, for example, a mixed solution of an organic acid and hydrofluoric acid.

Moreover, the oxidation may be conducted after the removal of SiO₂ in the oxygen ion implanted layer by immersing in the HF solution.

(7) Step of Planarizing and Thinning Surface of Wafer for Active Layer

The surface of the bonded wafer after the removal of the oxygen ion implanted layer is necessary to be planarized because it is rough as compared with the mirror polishing. As the planarization are applicable a heat treatment in a reducing atmosphere, a polishing process, a gas etching with a gas or an ion or a radical capable of etching Si, and the like.

Polishing Process

The bonding surface is slightly polished to improve the roughness. The polishing margin is preferable to be about 10-500 nm. When it is less than 10 nm, the roughness cannot be sufficiently improved, while when it exceeds 500 nm, the thickness uniformity of the active layer is deteriorated. By this treatment can be rendered the surface roughness (RMS) into not more than 0.5 nm.

Heat-Treatment in Reducing Atmosphere

The surface roughness of the bonded wafer is improved by heat-treating in Ar, H₂ or a mixed atmosphere thereof. The heat-treating temperature is preferable to be not lower than 1000° C. but not higher than 1300° C. As to the heat-treating time, a long time is required at a lower temperature, but it is preferable that the time is about 1-2 hours at 1000-1200° C., about 10-30 minutes at 1200-1250° C. and about 1-5 minutes above 1250° C. If the heat treatment is conducted under conditions of higher temperature and longer time exceeding the above values, there is a fear of deteriorating the in-plane thickness uniformity of the active layer due to the etching action of the reducing atmosphere.

As a heat-treating furnace are preferable a resistance heating type vertical furnace capable of simultaneously treating plural wafers, a lamp heating type RTA (high-speed temperature rising-descending furnace) treating individual wafers, and so on. particularly, RTA is effective in the treatment at a temperature of not lower than 1200° C.

By this heat treatment, the surface roughness (RMS) can be rendered into not more than 0.5 nm likewise the polishing process.

The removal of oxide film generated on the surface by this heat treatment may be attained by cleaning with HF solution or by etching through annealing with a hydrogen gas, Ar gas or a gas containing HF.

Thus, there can be obtained a bonded wafer being excellent in the thickness uniformity and having a planarized surface roughness and being less in the defect.

According to the invention, it is also possible to prepare a bonded wafer by directly bonding silicon wafers having different crystal orientations to each other (e.g. bonding of 110 crystal and 100 crystal, bonding of 111 crystal and 100 crystal, or the like).

### EXAMPLE 1

There are provided two silicon wafers of 300 mm in diameter sliced from a silicon ingot grown by CZ method and doped with boron. One of the two silicon wafers has a crystal orientation of (110) and is used as a wafer for active layer, and the other silicon wafer has a crystal orientation of (100) and is used as a wafer for support layer. Both the wafers are p-type silicon doped with boron and have a specific resistance of 1-20 Ωcm.

An oxide film having a thickness of 150 nm is formed on the (100) wafer by treating in an oxidizing atmosphere at 1000° C. for 5 hours.

Then, an oxygen ion implantation is carried out from the surface of the (110) wafer as the wafer for active layer at an acceleration voltage of 180 keV. The oxygen ion implantation is conducted at two stages, wherein the first ion implantation stage is carried out at a substrate-temperature of 200-600° C. and a dose is varied within a range of 1×10¹⁶−1×10¹⁸ atoms/cm². In the second ion implantation stage, the substrate temperature is within a range from room temperature to lower than 200° C. and a dose is varied within a range of 1×10¹⁴−5×10¹⁶ atoms/cm². As a result, an oxygen ion implanted layer is formed at a depth position of about 400 nm from the surface of the wafer for active layer.

Thereafter, the wafer for active layer is subjected to a heat treatment at 1200° C. in an argon gas atmosphere for 1 hour so that the form of the oxygen ion implanted layer is rendered into a relatively continuous state.

Next, both the wafers are subjected to cleaning with SCl, HF and O₃ to remove particles from the surfaces to be bonded and then bonded to each other. Thereafter, the bonded wafer is subjected to a heat treatment at 1100° C. in an oxidizing gas atmosphere for 2 hours for strongly bonding the bonded interface.

Then, the wafer for active layer in the bonded wafer is ground by a given thickness from the surface thereof by using a grinding apparatus. That is, the grinding treatment is carried out at the surface side of the oxygen ion implanted layer so as to leave only a part of the wafer for active layer (corresponding to a thickness of about 5 μm).

Then, the oxygen ion implanted layer is exposed by polishing the surface of the bonded wafer after the grinding while feeding a polishing agent having an abrasive (silica) concentration of not more than 1 mass %. As the polishing agent is used an alkaline solution having an abrasive concentration of not more than 1 mass %. The alkaline solution is an organic alkali solution composed mainly of amine (e.g. piperazine, ethylene diamine or the like).

Moreover, it has been confirmed that the resulting oxygen ion implanted layer is uniformly formed in the bonded wafer, resulting in the exposure of the oxygen ion implanted layer formed uniformly in the bonded wafer.

Thereafter, the bonded wafer is subjected to a wet oxidation treatment in an oxidizing atmosphere at a temperature of 950° C. for 0.5 hour. As a result, an oxide film having a thickness of 150 nm is formed on the exposed surface of the oxygen ion implanted layer. Next, the oxide film is removed by HF etching (concentration of HF: 10%, temperature: 20° C.). After the removal of the oxide film, the thickness of the exposed active layer is uniformized and thinned in the surface.

Then, the bonded wafer is cleaned by the following treatment. The bonded wafer is immersed in several solutions respectively in order of: an aqueous solution of ozone dissolved at an ozone concentration of 5 ppm, an aqueous solution containing 0.06 mass % of citric acid as an organic acid relative to pure water, an aqueous solution containing 0.05 mass % of hydrofluoric acid, an aqueous solution containing 0.6 mass % of citric acid as an organic acid relative to pure water and finally an aqueous solution of ozone dissolved at an ozone concentration of 5 ppm and a room temperature. Each of the cleaning treatments is conducted at room temperature for 5 minutes. By this cleaning treatment are removed metal impurity and particles from the surface of the bonded wafer.

After the above cleaning, the bonded wafer is subjected to a heat treatment in an argon gas atmosphere at 1200° C. for 1 hour to finish the bonded wafer.

The thus obtained active layer has a thickness of 100-200 nm and the scattering in the thickness distribution in the surface is within a range of 10-20%.

### EXAMPLE 2

A bonded wafer is prepared under the same conditions as in Example 1 except that the (110) wafer for active layer is bonded to the (100) wafer for support layer without an insulating film (an oxide film). The thus obtained active layer has a thickness of 100-200 nm and the scattering in the thickness distribution in the surface is within a range of 10-20%.

Next, the defect density of the bonded wafers obtained in Examples 1 and 2 is investigated.

The form of defects generated differs between Example 1 using the insulating film and Example 2 not using the insulating film.

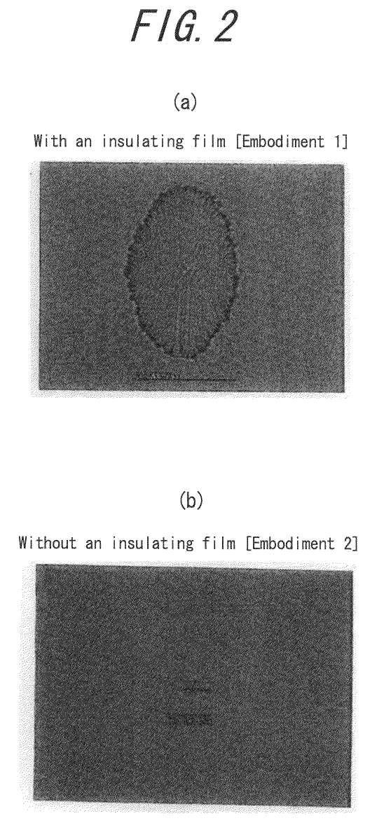

FIGS. 2(a) and 2(b) show optical microphotographs of crystal defects generated on the wafer surfaces in Examples 1 and 2, respectively. When the bonding is carried out with the oxide film (Example 1), an ellipsoidally-shaped defect (diameter: 100-500 μm) is observed and also the oxide film is observed in such a defect. On the other hand, when the bonding is carried out without the oxide film (Example 2), a linearly-shaped defect (length: 10-100 μm) is observed. These defects can be observed as bright points by visually observing the appearance of the bonded wafer with a light focusing lamp.

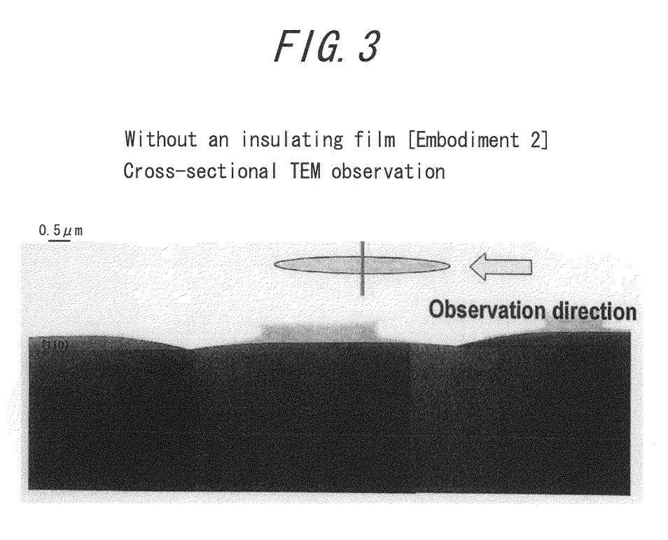

When the cross-section of the linearly-shaped defect is observed by TEM, it has been confirmed that the top layer is lost as shown in FIG. 3. Also, the defect density in Examples 1 and 2 is dependent on the conditions for oxygen ion implantation in the same tendency regardless of the presence or absence of the oxide film. That is, the main mechanism of generating the defect is the same in both the examples and it is considered that the oxygen ion implantation is a cause of generating the defect.

The difference of the defect form between the ellipsoidally-shaped defect and linearly-shaped defect results from the presence or absence of the oxide film. It is guessed that when the defect introduced into the active layer in the bonding process is selectively etched in the annealing of Ar atmosphere at the final step, if the oxide film is not existent, the defect is etched as it is, while if the oxide film is existent, the etching is promoted while reacting Si with SiO₂ in the oxide film to form SiOx having a low vapor pressure and hence the defect is changed into an ellipsoid of a large size.

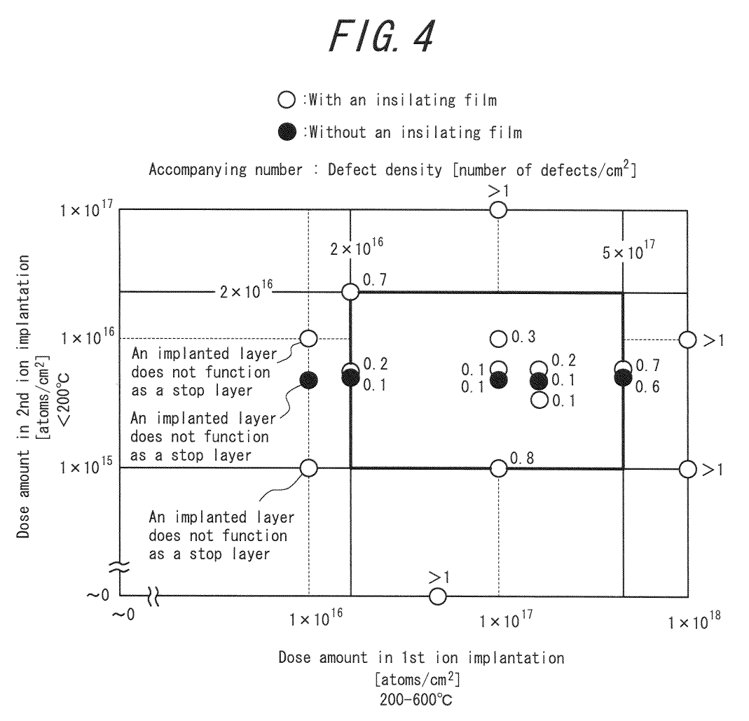

The defect density is determined by visually observing an appearance of a ¼ area of 300 mm wafer obtained under each condition in a light focusing lamp to count the number of bright points. The obtained results are shown in FIG. 4.

As shown in FIG. 4, when the oxygen ion implantation is divided into two stages according to the invention and the first oxygen ion implantation stage is conducted under conditions of the substrate temperature: 200-600° C. and the dose: 2×10¹⁶−5×10¹⁷ atoms/cm² and the second ion implantation stage is conducted under conditions of the substrate temperature: lower than 200° C. and the dose: 1×10¹⁵−2×10¹⁶ atoms/cm², the defect density is an extremely low value of less than 1/cm² regardless of the presence or absence of the insulating film.

What is claimed is:

1. A method for producing a bonded wafer by bonding a wafer for active layer to a wafer for support layer with or without an insulating film and then thinning the wafer for active layer, which comprises time-orientedly combining:
(1) a step of forming an oxygen ion implanted layer in the wafer for active layer through at least two stages comprising a first implantation stage of implanting oxygen ions at a dose of 2×10¹⁶−5×10¹⁷ atoms/cm² into the wafer for active layer being at a state of not lower than 200° C. and a second implantation stage of implanting oxygen ions at a dose of 1×10¹⁵−2×10¹⁶ atoms/cm² into the wafer for active layer being at a state of lower than 200° C.;
(2) a step of subjecting the wafer for active layer to a first heat treatment at a temperature of not lower than 1000° C. in a non-oxidizing atmosphere;
(3) a step of bonding the wafer for active layer to the wafer for support layer directly or with an insulating film;
(4) a step of subjecting the bonded wafer to a second heat treatment to improve the bonded strength;
(5) a step of thinning a portion of the wafer for active layer in the bonded wafer to expose the oxygen ion implanted layer;
(6) a step of removing the oxygen ion implanted layer from the wafer for active layer in the bonded wafer; and
(7) a step of planarizing and/or thinning the surface of the wafer for active layer in the bonded wafer.

2. A method for producing a bonded wafer according to claim 1, wherein a crystal orientation of each wafer face in the bonded wafer is a combination of (100) and (110) or (111).
